(19) United States
(12) Patent Application Publication
(10) Pub. No.: US 2026/0271153 A1
(43) Pub. Date: Sep. 10, 2026

(54) OPTOELECTRONIC DEVICE CONTROLLERS CONFIGURABLE FOR MODULATING LIGHT OUTPUT OF OPTOELECTRONIC DEVICES

(71) Applicant: TEXAS INSTRUMENTS INCORPORATED, Dallas, TX (US)

(72) Inventor: Aaron Lee, Garland, TX (US)

(21) Appl. No.: 19/559,133

(22) Filed: Mar. 6, 2026

Related U.S. Application Data
(60) Provisional application No. 63/769,220, filed on Mar. 10, 2025.

(51) Int. Cl. H05B 45/325; H01S 3/10; H05B 45/14; H05B 45/18; H05B 47/14; H05B 47/16; H05B 47/165

(52) U.S. Cl. CPC H05B 45/325; H01S 3/10; H05B 45/14; H05B 45/18; H05B 47/14; H05B 47/16; H05B 47/165

(57) ABSTRACT

An optoelectronic device controller includes a first circuit configurable to generate a pulse width modulation signal based at least in part on (i) an adjustable threshold voltage and (ii) a periodic waveform, and a second circuit configurable to modulate light output of an optoelectronic device based at least in part on the pulse width modulation signal. The periodic waveform may be an output of a triangle wave generator. The optoelectronic device may be one of a laser and a light-emitting diode.

### TECHNICAL FIELD

The present disclosure relates to the field of optoelectronic devices, such as light-emitting diodes (LEDs) and lasers, and methods of controlling the same.

### BACKGROUND

Optoelectronic devices may utilize solid-state light sources, such as light emitting diodes and laser diodes. Solid-state light sources offer various technical advantages, including rapid turn-on, rapid cycling (e.g., on-off-on) times, long useful lifespan, low power consumption, narrow emitted light bandwidths that eliminate the need for color filters to provide desired colors, etc. Solid-state light sources can be illuminated with a sequence of current pulses. For example, a pulse width modulation (PWM) circuit may be used to generate a drive current to pulse the solid-state light source on and off, using the duty cycle to control the light output.

### SUMMARY

The present disclosure describes optoelectronic device controllers, and methods of fabrication and use thereof that enable modulating of light output of optoelectronic devices utilizing pulse width modulation signals that are based at least in part on adjustable threshold voltages and periodic waveforms. This summary is not an extensive overview of the disclosure. Rather, a purpose of the summary is to present some examples of the present disclosure in a simplified form as a prelude to a more detailed description that is presented later.

In some examples, an optoelectronic device controller includes a first circuit configurable to generate a pulse width modulation signal based at least in part on (i) an adjustable threshold voltage and (ii) a periodic waveform, and a second circuit configurable to modulate light output of an optoelectronic device based at least in part on the pulse width modulation signal.

The periodic waveform may be an output of a triangle wave generator.

The optoelectronic device may be one of a laser and an LED.

The adjustable threshold voltage may control a duration of pulses of the pulse width modulation signal.

The optoelectronic device controller may further include a third circuit providing a clock source shared by the first circuit and the second circuit. The second circuit may be configurable to generate an optoelectronic device enable control signal synchronized to the clock source, and to generate a voltage pulse signal controlling switching of the optoelectronic device on and off as a logical AND of the optoelectronic device enable control signal and the pulse width modulation signal. The second circuit may be configurable to apply the voltage pulse signal to a transistor, the transistor gating current through the optoelectronic device based at least in part on the voltage pulse signal. The voltage pulse signal may be applied to the transistor via a field-effect transistor driver.

The optoelectronic device controller may further include a third circuit configurable to monitor a peak current of the optoelectronic device utilizing a peak detector circuit, the peak detector circuit tracking a peak voltage across a current sense resistor in a current path of the optoelectronic device, and to control an output voltage level of a constant voltage source for the optoelectronic device based at least in part on the peak current. The third circuit may be further configurable to control the output voltage level of the constant voltage source at least in part on at least one of: a temperature of the optoelectronic device; a duty cycle of the optoelectronic device; an amount of time that the optoelectronic device has been on; aging of hardware component of the optoelectronic device; and a measured efficiency of the optoelectronic device.

The second circuit may be configurable to modulate the light output of the optoelectronic device to provide luminance control for the optoelectronic device.

In some other examples, a light projection system includes a laser light source configured to emit a laser beam, and a laser controller including a first circuit configurable to generate a pulse width modulation signal based at least in part on (i) an adjustable threshold voltage and (ii) a periodic waveform, and a second circuit configurable to modulate the laser beam emitted by the laser light source based at least in part on the pulse width modulation signal.

The first circuit of the laser controller may be configurable to set the adjustable threshold voltage to control a duration of one or more pulses of the pulse width modulation signal, a luminance of the laser beam being based at least in part on the duration of the one or more pulses of the pulse width modulation signal.

The second circuit of the laser controller may be configurable to generate a laser enable control signal synchronized to a clock source, and to generate a voltage pulse signal controlling switching of the laser light source on and off as a logical AND of the laser enable control signal and the pulse width modulation signal.

The laser controller may further include a third circuit configurable to monitor a peak current of the laser light source utilizing a peak detector circuit, the peak detector circuit tracking a peak voltage across a current sense resistor in a current path of the laser light source, and to control an output voltage level of a constant voltage source for the laser light source based at least in part on the peak current.

In some additional examples, a method includes determining a target luminance level for an optoelectronic device, selecting, based at least on the target luminance level, a threshold voltage value for a pulse width modulation circuit, generating, utilizing the pulse width modulation circuit, a pulse width modulation signal based at least in part on (i) the selected threshold voltage value and (ii) a periodic waveform, and modulating light output of the optoelectronic device based at least in part on the pulse width modulation signal.

The optoelectronic device may be one of a laser and an LED.

A duration of one or more pulses of the pulse width modulation signal may be based at least in part on the selected threshold voltage value.

Modulating the light output of the optoelectronic device may comprise generating a voltage pulse signal controlling switching of the optoelectronic device on and off as a logical AND of an optoelectronic device enable control signal and the pulse width modulation signal.

The method may further include monitoring, utilizing a peak detector circuit, a peak current of the optoelectronic device, the peak detector circuit being configurable to track a peak voltage across a current sense resistor in a current path of the optoelectronic device, and controlling an output voltage level of a constant voltage source for the optoelectronic device based at least in part on the monitored peak current of the optoelectronic device.

### BRIEF DESCRIPTION OF THE DRAWINGS

FIG. 1 is a block diagram of a system implementing an optoelectronic device controller configurable for modulating light output of an optoelectronic device in accordance with one or more examples of the present disclosure;

FIG. 2 is another block diagram of a system implementing an optoelectronic device controller configurable for modulating light output of an optoelectronic device in accordance with one or more examples of the present disclosure;

FIGS. 3A and 3B show clock signals, adjustable threshold voltages and periodic waveforms configured for generating a pulse width modulation signal for use by an optoelectronic device controller in modulating light output of an optoelectronic device in accordance with one or more examples of the present disclosure;

FIG. 4 shows a circuit diagram of an optoelectronic device control circuit for implementing an optoelectronic device controller configurable for modulating light output of an optoelectronic device in accordance with one or more examples of the present disclosure;

FIG. 5 shows a circuit diagram of a high speed pulse width modulation circuit configurable for generating a high speed pulse width modulation signal for use by an optoelectronic device controller configurable for modulating light output of an optoelectronic device in accordance with one or more examples of the present disclosure;

FIG. 6 shows a circuit diagram of an optoelectronic device voltage control circuit configurable for generating a voltage output signal for use by an optoelectronic device controller configurable for modulating light output of an optoelectronic device in accordance with one or more examples of the present disclosure;

FIG. 7 shows a circuit diagram of a triangle wave generator circuit configurable for generating a periodic waveform for use by an optoelectronic device controller configurable for modulating light output of an optoelectronic device in accordance with one or more examples of the present disclosure;

FIGS. 8A-8F show a circuit diagram of an optoelectronic device control circuit including a triangle wave generator circuit, a high speed pulse width modulation generator circuit and an optoelectronic device voltage control circuit in accordance with one or more examples of the present disclosure;

FIGS. 9A-9D show a circuit diagram of another optoelectronic device control circuit including a triangle wave generator circuit, a high speed pulse width modulation generator circuit and an optoelectronic device voltage control circuit in accordance with one or more examples of the present disclosure;

FIG. 10 shows a flow diagram of a methodology for utilizing an optoelectronic device controller for modulating light output of an optoelectronic device in accordance with one or more examples of the present disclosure;

FIGS. 11A and 11B are schematic diagrams of a light projection system in accordance with one or more examples of the present disclosure;

FIG. 12 is another schematic diagram of a light projection system in accordance with one or more examples of the present disclosure;

FIGS. 13A and 13B are additional schematic diagrams of a light projection system in accordance with one or more examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Optoelectronic device drivers (e.g., LED drivers, laser drivers, etc.) may use a current control feedback loop to keep the brightness of one or more optoelectronic devices (e.g., LEDs, lasers, etc.) at a specific level. In some cases, the light output from one or more optoelectronic devices needs to be a specific amount during a first time window, and another specific amount in an adjacent second time window, where the first and second time windows are short time windows (e.g., microseconds or less). Controlling the brightness of an optoelectronic device such as an LED or laser precisely over such short time windows presents technical challenges for conventional approaches which utilize standard LED/laser drivers with current control feedback loops.

Luminance or brightness control is important in various applications. For example, a very wide range of dimming may be required in certain systems, such as automative heads-up display (HUD) systems, to accommodate different ambient light conditions. For emerging HUD system technology using lasers and holographic optical elements (HOEs), the use of LED/laser drivers with current control feedback loops is the only developed option to achieve dimming requirements for digital light processing (DLP) technology.

Conventional approaches for providing dimming (e.g., for DLP HUD systems) relies on scaling the LED current using an LED driver, and using a photodiode in the optical path for controlling the size of light pulses. These are two distinct operation modes which must be used, which are difficult to combine in practice. Controlling the current via an LED driver, for example, is not generally responsive enough for very short pulses, and also cannot be relied on in laser-based systems. Using these modes results in a high degree of system complexity which must be dealt with by end-users.

Illustrative examples of the present disclosure provide optoelectronic device controllers configured to modulate the light output of optoelectronic devices such as LEDs and lasers. In some examples, the optoelectronic device controllers include or utilize circuitry for generating fast pulses for LED or laser light with variable duty cycle. High speed pulse width modulation (HSPWM) may be used to modulate the light output, where a HSPWM signal is generated by comparing an adjustable threshold voltage (VADJ) with a periodic waveform such as a triangle wave voltage (VTRI). VTRI, in some examples, is derived from a clock source (CLK) that is shared with or part of the optoelectronic device controller, such as using a resistor-capacitor (RC) circuit and a transistor (e.g., a field-effect transistor (FET)). It should be noted that, while various examples are described herein with respect to use of a periodic waveform that is a triangle wave, this is just an example. Further, the triangle wave does not need to be strictly triangular. Instead, the triangle wave or more generally the periodic waveform should be a shape which allows for multiple duty cycles to be generated after comparison with multiple threshold voltages (e.g., such that by varying VADJ, multiple different duty cycles may be generated by a HSPWM circuit).

In some examples, the optoelectronic device controller may further modulate the light output of an optoelectronic device by generating a digital optoelectronic device enable control signal (e.g., LED_EN for an LED), which is synchronized to the clock source (CLK). A signal (VPULSE) which controls the switching of the optoelectronic device (e.g., on and off) may be generated or determined as a logical AND between the HSPWM signal and the digital optoelectronic device enable control signal (e.g., LED_EN). VPULSE controls a transistor (e.g., a FET) or other switch, possibly via a FET driver, which in turn gates the current through the optoelectronic device.

A peak current of the optoelectronic device (e.g., an LED, a laser, etc.), in some examples, is monitored via an analog-to-digital controller (ADC) that measures the voltage on a peak detector circuit. The peak detector circuit tracks the peak voltage across a current sense resistor in a current path of the optoelectronic device. The measured peak detector voltage provides feedback to the optoelectronic device controller. The optoelectronic device controller uses this data to control the output voltage level of a constant voltage source which serves as a supply to the optoelectronic device. The appropriate voltage level can be determined by an algorithm that takes into account various parameters or information such as one or more of: measured voltage from the peak detector circuit, a temperature of the optoelectronic device, a duty cycle of the optoelectronic device, an amount of time that the optoelectronic device has been on, aging of components of the optoelectronic device, a measured efficiency of the optoelectronic device, other metrics, etc. Using the peak detector circuit and the ADC for tracking the current of the optoelectronic device is used, in some examples, because of the very short duration of the pulses.

In some examples, the HSPWM is used to modulate light output of the optoelectronic device, where a PWM signal is generated based on comparing a periodic waveform (e.g., a triangle wave) to an adjustable threshold voltage (VADJ). Controlling and limiting of current supplied to the optoelectronic device may be achieved by using a combination of a peak detector circuit, a controller (e.g., an ADC) and an adjustable constant voltage source. For systems which use a constant current switching supply, an optoelectronic device (e.g., an LED, a laser, etc.) which is actively passing current will generally have ripple as the supply switches. In some examples, because the supply voltage of the optoelectronic device is adjusted over long time scales, the variation in brightness during on-time will generally be lower. In some examples, the optoelectronic device controller allows for high resolution control of light output levels of optoelectronic devices over small time scales. Further, smaller pulses are able to be generated. The optoelectronic device may use a triangle wave or other periodic waveform to generate a HSPWM signal for modulating the light output of an optoelectronic device. Further, some examples may use a current sense resistor, a peak detector circuit, an ADC and a controlled and variable voltage source in a feedback loop to control current supplied to the optoelectronic device.

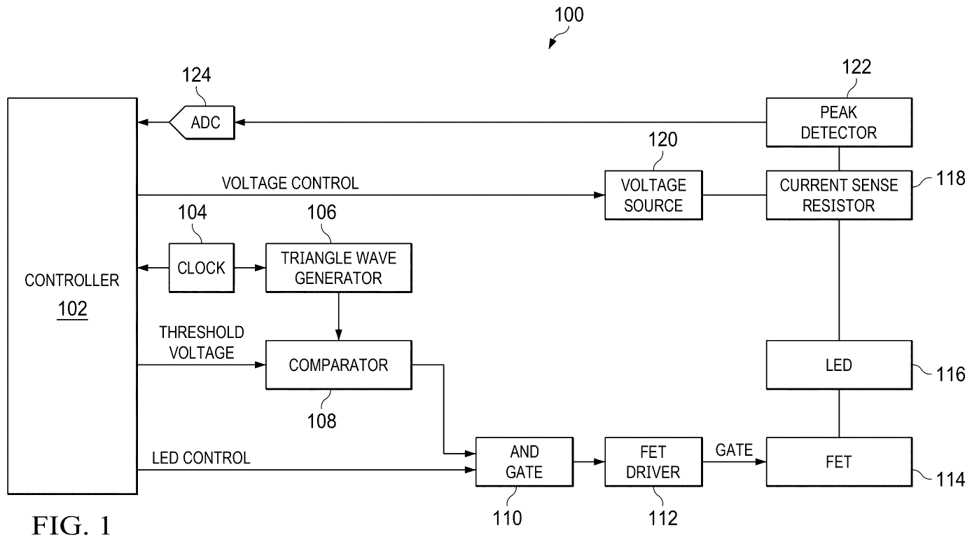

Referring now to FIG. 1, an optoelectronic device control system 100 for an optoelectronic device (e.g., an LED, a laser, etc.) is shown. The system 100 includes an optoelectronic device controller 102, also referred to as controller 102. The controller 102 receives input from clock 104 providing a clock source (CLK). The controller 102 sets an adjustable threshold voltage (VADJ) which controls a variable duty cycle for a HSPWM signal. The HSPWM signal is produced by a comparator 108, which takes as input the adjustable threshold voltage value set by the controller 102 and a periodic waveform (e.g., a triangle wave) that is output by a triangle wave generator 106 that shares the clock source (e.g., clock 104) with the controller 102. The comparator 108 outputs the HSPWM signal, with pulses corresponding to portions of the periodic waveform output by the triangle wave generator 106 that exceed or fall below the adjustable threshold voltage set by the controller 102. The controller 102 also produces an LED control signal (e.g., LED_EN) for an optoelectronic device, implemented in the FIG. 1 example as LED 116. The LED control signal and the output of the comparator 108 are provided to an AND gate 110, which generates a voltage pulse signal (e.g., for turning the LED 116 on and off) as a logical AND of the LED control signal and the output of the comparator 108. The voltage pulse signal output by the AND gate 110 is provided to the LED 116, in the FIG. 1 example via an optional FET driver 112 coupled to a gate of a FET 114 coupled to the LED 116. The controller 102 further produces or outputs a voltage control signal that is provided to a voltage source 120 coupled to the LED 116 via a current sense resistor 118. A peak detector circuit 122 is coupled to the current sense resistor 118. The peak detector circuit 122 tracks the peak voltage across the current sense resistor 118. The peak current is monitored by the controller 102 via an ADC 124 the measures the voltage on the peak detector circuit 122.

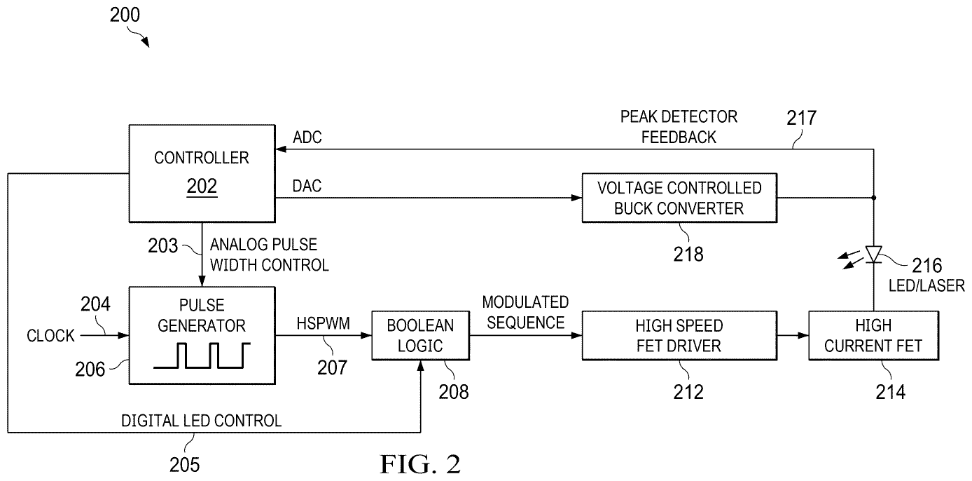

Referring now to FIG. 2, an optoelectronic device control system 200 for an optoelectronic device (e.g., an LED, a laser, etc.) is shown. The system 200 includes an optoelectronic device controller 202, also referred to as controller 202. The controller 202 produces an analog pulse width control signal 203 and a digital LED control signal 205. The analog pulse width control signal 203 and a clock signal 204 are input to a pulse generator circuit 206 which produces a HSPWM signal 207. The analog pulse width control signal 203 sets an adjustable threshold voltage value that is used by the pulse generator circuit 206. The pulse generator circuit 206 may compare this adjustable threshold voltage value against a generated periodic waveform (e.g., a triangle wave) to produce the HSPWM signal 207. Boolean logic 208 receives the digital LED control signal 205 and the HSPWM signal 207, and outputs a modulated sequence (e.g., a logical AND of the HSPWM signal 207 and the digital LED control signal 205) to a high speed FET driver 212 coupled to a high current FET 214 coupled to an optoelectronic device, implemented in the system 200 as LED/laser 216. A peak detector feedback signal 217 tracks the peak current of the LED/laser 216. The controller 202 performs ADC of the peak detector feedback signal 217, and uses this data or information to control the output voltage level of a constant voltage source, shown in FIG. 2 as the voltage-controlled Buck converter 218, coupled to the LED/laser 216. The controller 202 performs digital-to-analog conversion (DAC) of a digital output voltage control signal to provide the input to the voltage-controlled Buck converter 218.

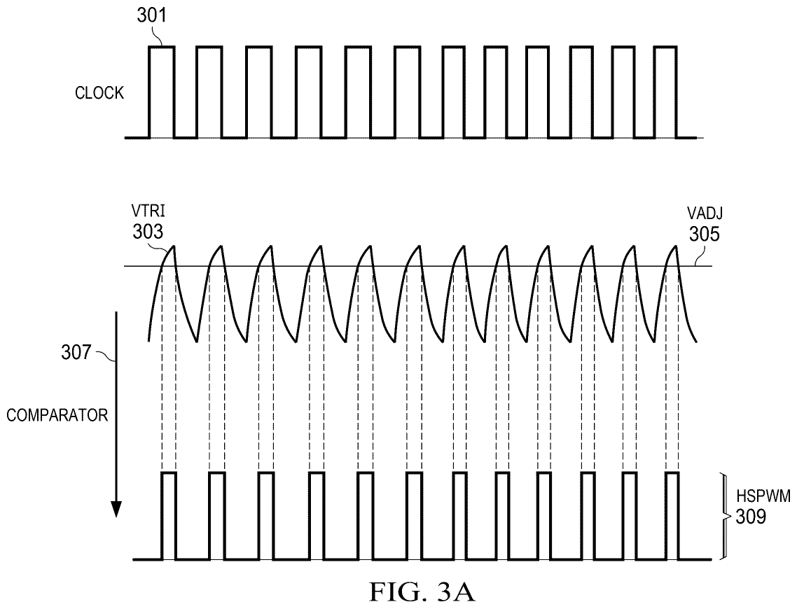

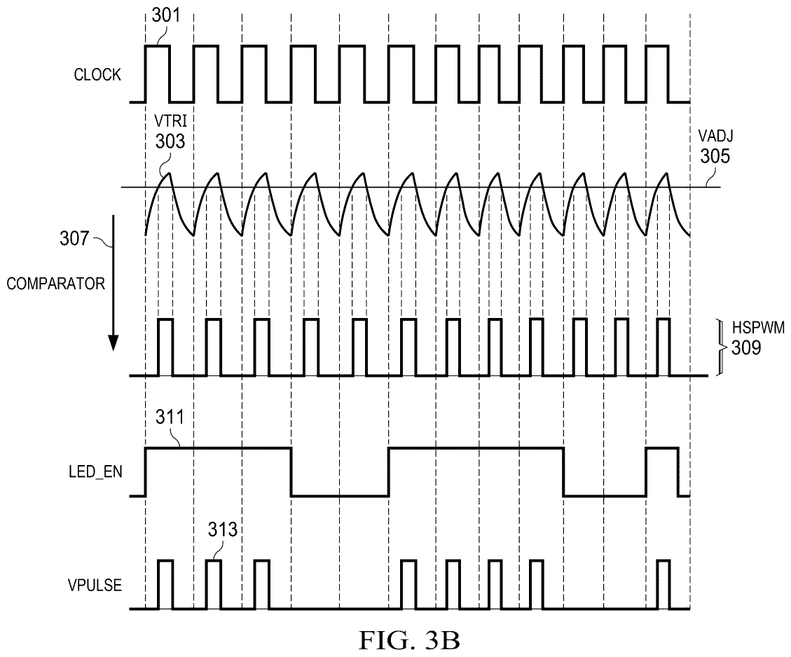

Referring now to FIGS. 3A and 3B, generation of a HSPWM signal (e.g., the output of the comparator 108 in FIG. 1, the HSPWM signal 207 in system 200) is illustrated. FIG. 3A shows a clock signal 301 (e.g., provided by clock 104 in system 100, the clock signal 204 in system 200), a periodic waveform illustrated as a triangle wave voltage (VTRI) 303 (e.g., an output of the triangle wave generator 106 in system 100), and an adjustable threshold voltage (VADJ) 305 (e.g., the threshold voltage output by the controller 102 in system 100, the analog pulse width control signal 203 in system 200). Comparator logic 307 (e.g., comparator 108 in system 100) is applied to the VTRI 303 and VADJ 305 to produce HSPWM signal 309. The HSPWM signal 309 includes pulses that are “high” or logic 1 when the VTRI 303 exceeds VADJ 305 as illustrated. FIG. 3B further shows an optoelectronic device enable control signal (LED_EN) 311 (e.g., the LED control signal output by the controller 102 in system 100, the digital LED control signal 205 in system 200), and a voltage pulse control signal (VPULSE) 313 (e.g., the output of the AND gate 110 in system 100, the modulated sequence produced by the Boolean logic 208 in system 200). As illustrated, VPULSE 313 includes ones of the voltage pulses of the HSPWM signal 309 which are coincident with LED_EN 311 being “high” or logic 1.

The HSPWM signal 309 is used to modulate light output of an optoelectronic device (e.g., an LED, a laser, etc.), where the PWM is generated by comparing VADJ 305 with VTRI 303. VTRI 303 is derived from a clock source (e.g., clock signal 301) that is shared with an optoelectronic device controller that produces the optoelectronic device enable control signal, LED_EN 311. This may be implemented, in some examples, using an RC circuit and FET. It should be noted that VTRI 303, which is an example of what is more generally referred to herein as a periodic waveform, provides a triangular waveform. The triangular waveform, however, does not need to be strictly triangular. The periodic waveform instead need only be a shape which allows for multiple different duty cycles (e.g., for pulses of the HSPWM signal 309) to be generated after comparison with multiple values for VADJ 305 (e.g., as VADJ 305 is adjusted, the duty cycle for pulses of the HSPWM signal 309 changes). Through combination with LED_EN 311, an optoelectronic device controller is able to produce VPULSE 313 enabling high speed luminance control for an optoelectronic device. The optoelectronic device controller may further modulate the light output of the optoelectronic device by generating a digital control signal, LED_EN 311, which is synchronized to the clock signal 301. The resulting signal VPULSE 313 controls the switching of the optoelectronic device, where VPULSE 313 is a logical AND between the HSPWM signal 309 and LED_EN 311. VPULSE 313 controls a FET or other switch (e.g., FET 114 in system 100, high current FET 214 in system 200) via a FET driver (e.g., FET driver 112 in system 100, high speed FET driver 212 in system 200), which in turn gates the current through the optoelectronic device (e.g., LED 116 in system 100, LED/laser 216 in system 200).

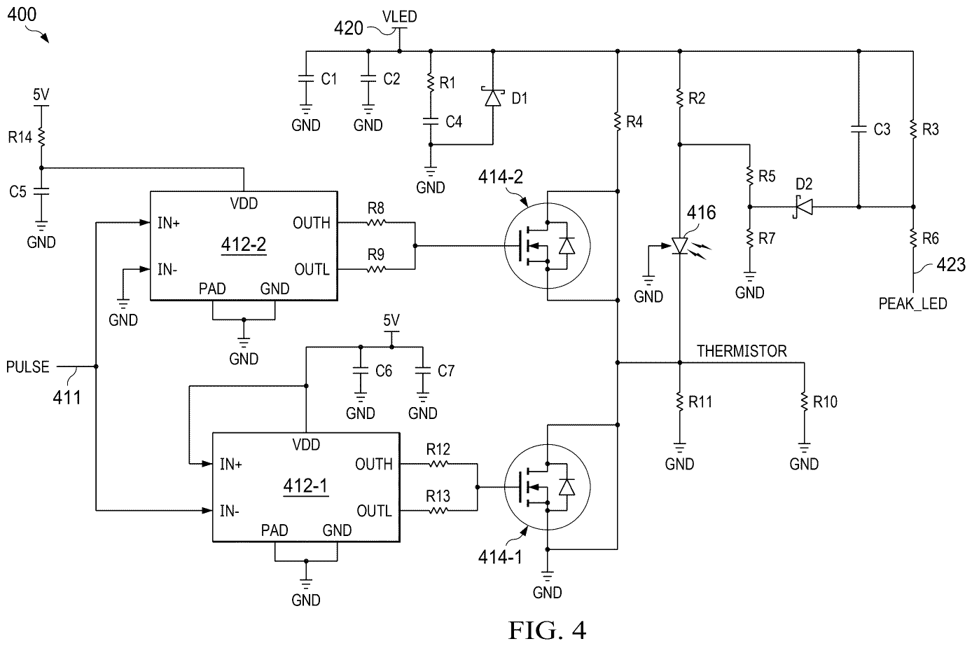

FIG. 4 shows a circuit diagram of control circuit 400 (e.g., an optoelectronic device control circuit, also referred to as an LED/laser control circuit) for an optoelectronic device 416 (e.g., an LED/laser). The control circuit 400 receives an input pulse signal 411. In the circuit shown, the optoelectronic device 416 is “on” when the pulse signal 411 is “low” (e.g., 0). The pulse signal 411 is provided to a set of FET drivers 412-1 and 412-2 (collectively, FET drivers 412) with outputs coupled to control FETs 414-1 and 414-2 (collectively, FETs 414). The FETs 414 are coupled to the optoelectronic device 416. The optoelectronic device 416 includes a first terminal (1) coupled to a constant voltage source 420 (VLED), a second terminal (2) coupled to the outputs of the FETs 414, and a third terminal (3) coupled to ground (GND). A peak voltage 423 of the optoelectronic device 416 is tracked over time for peak current detection as described herein.

The control circuit 400 includes capacitors (C), diodes (D), and resistors (R) interconnected with components of the control circuit 400 as illustrated. In some examples, the capacitors in the control circuit 400 have the following capacitance values: C1=22 microFarads (uF), C2=220 nanoFarads (nF), C3=47 picoFarads (pF), C4=1 nF, C5=1 uF, C6=1 uF, and C7=10 uF. The diodes D1 and D2 in the control circuit 400 may be respective Schottky diodes. The resistors in the control circuit 400 may have the following resistance values: R1=1 ohms (Ω), R2=100 milliohms (mΩ), R3=200 kiloohms (kΩ), R4=~0 Ω, R5=560 Ω, R6=~0 Ω, R7=1 kΩ, R8=200 mΩ, R9=200 mΩ, R10 is implemented as a thermistor, R11=1 Ω, R12=200 mΩ, R13=200 mΩ, and R14=~0 Ω. In other examples, however, these capacitance and resistance values may be varied.

The peak current of the optoelectronic device 416 is monitored via an ADC (not shown in FIG. 4) that measures the voltage on a peak detector circuit (e.g., peak voltage 423), which tracks the peak voltage across a current sense resistor (e.g., R2) in the current path of the optoelectronic device 416. The measured peak detector voltage (e.g., peak voltage 423) provides feedback to a controller (e.g., controller 102 in system 100, controller 202 in system 200). Monitoring the peak current in this way advantageously enables higher speed operation. The controller uses this information (e.g., the peak voltage 423) to control the output voltage level of a constant voltage source (e.g., VLED 420) which serves as the supply to the optoelectronic device 416. The appropriate voltage level, in some examples, is determined based at least in part on: the measured voltage (e.g., the peak voltage 423) from the peak detector circuit; the temperature of the optoelectronic device 416; a duty cycle of the optoelectronic device 416; an amount of time that the optoelectronic device 416 has been on; a measured efficiency of the optoelectronic device 416; and other metrics. Use of the peak detector and the ADC in tracking the current of the optoelectronic device 416 is needed in some examples because of the very short duration of the pulses (e.g., of the pulse voltage 411).

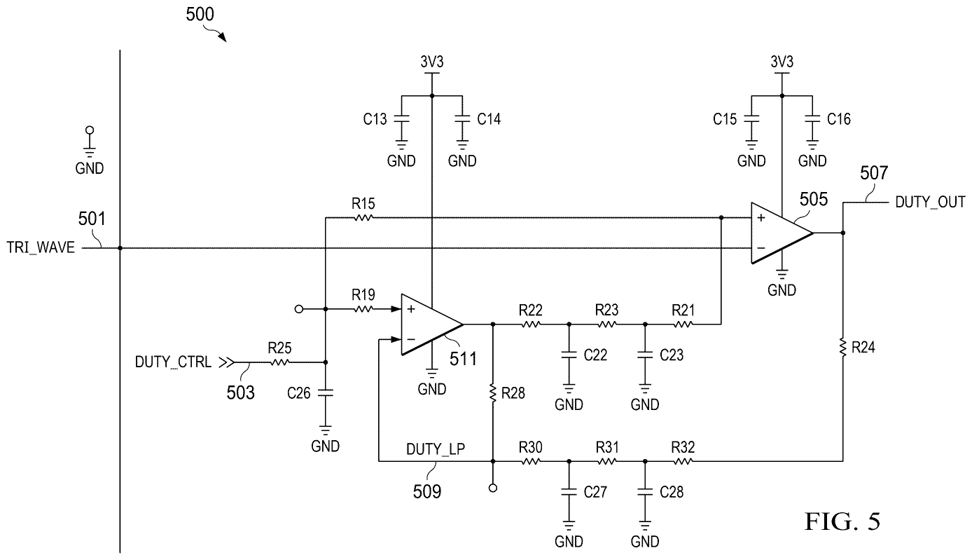

FIG. 5 shows a circuit diagram of an HSPWM circuit 500. The HSPWM circuit 500 receives as input a periodic waveform via triangle wave signal 501 (TRI_WAVE), and a duty cycle control generation signal 503 (DUTY_CTRL) which are input to operational amplifier 505. The operational amplifier 505 has a first terminal (1) which outputs a duty cycle output signal 507 (DUTY_OUT), a second terminal (2) coupled to ground (GND), a third terminal (3) coupled to the duty cycle control generation signal 503, a fourth terminal (4) coupled to the triangle wave signal 501, and a fifth terminal (5) coupled to a voltage supply (3V3, providing 3.3 V in some examples). The HSPWM circuit 500 provides a negative feedback mechanism for stability, with a control loop provided via operational amplifier 511 that compares the input duty cycle control generation signal 503 to the average of a low pass filtered version of the duty cycle output signal 507, shown as filtered duty cycle output signal 509 (DUTY_LP). The operational amplifier 511 has a first terminal (1) that is coupled to the third terminal (3) of the operational amplifier 505, a second terminal (2) that is coupled to ground (GND), a third terminal (3) that is coupled to the duty cycle control generation signal 503, a fourth terminal (4) that is coupled to the filtered duty cycle output signal 509, and a fifth terminal (5) that is coupled to a voltage supply (3V3).

The operational amplifier 511 compares the input DUTY_CTRL to the average of DUTY_OUT, provided as DUTY_LP. The output of the operational amplifier 511 increases as DUTY_LP goes lower than DUTY_CTRL. DUTY_LP is DUTY_OUT after passing through a low pass filter. The operational amplifier 511 gives the low pass filtered input to the non-inverting input of the operational amplifier 505. The operational amplifier 505 takes the triangle wave signal 501 on its inverting input. As the non-inverting input of the operational amplifier 505 goes higher, the duty cycle of the PWM from the operational amplifier 505 output (e.g., DUTY_OUT) goes higher, which completes the negative feedback loop. In the HSPWM circuit 500, second order cascaded low pass filters are used for frequency selectivity.

The HSPWM circuit 500 includes various capacitors (C) and resistors (R) interconnected as illustrated. In some examples, the capacitors of the HSPWM circuit 500 have the following capacitance values: C13=10 uF, C14=1 uF, C15=10 uF, C16=1 uF, C22=22 pF, C23=22 pF, C26=10 uF, C27=1000 pF, C28=1000 pF. The resistors of the HSPWM circuit 500 may have the following resistance values: R15=~0 Ω, R19=~0 Ω, R21=~0 Ω, R22=3.0 kΩ, R23=3.9 kΩ, R24=~0 Ω, R25=20 kΩ, R28=3.9 kΩ, R30=3.9 kΩ, R31=3.9 kΩ, and R32=3.9 kΩ. In other examples, however, these capacitance and resistance values may be varied.

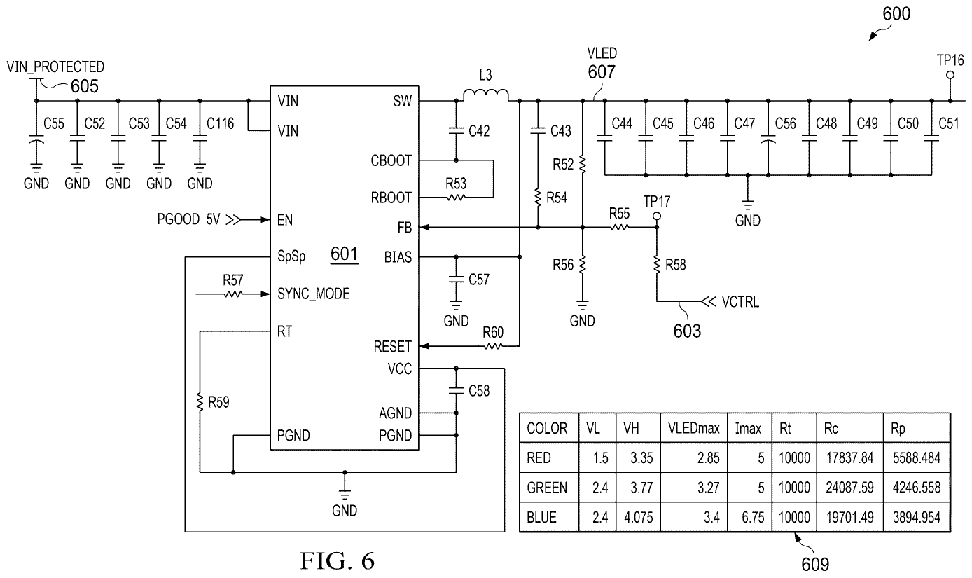

FIG. 6 shows an optoelectronic device voltage control circuit 600, including a buck converter 601 that produces a voltage output signal 607 (VLED) provided as a voltage source to an optoelectronic device (e.g., an LED, a laser, etc.). The buck converter 601 includes various terminals, including an FB input pin (terminal 7) that is coupled to a voltage control signal 603 (VCTRL) via a resistor (R55). The resistor R55 is added to pull the FB input pin of the buck converter 601 toward VCTRL. A voltage input signal 605 (VIN_PROTECTED) is supplied to the VIN pins (terminals 2 and 14) of the buck converter 601. The effect of this is to change the value of the voltage output signal 607 (VLED) that causes the FB node of the buck converter 601 to equal 1.0 V.

The optoelectronic device voltage control circuit 600 includes various capacitors (C), an inductor (L) and resistors (R) interconnected as illustrated. In some examples, the capacitors of the optoelectronic device voltage control circuit 600 have the following capacitance values: C42=220 nF, C43—15 pF, C44=22 uF, C45=22 uF, C46=22 uF, C47=22 uF, C48=22 uF, C49=22 uF, C50=22 uF, C51=22 uF, C52=470 nF, C53=470 nF, C54=10 uF, C55=150 uF, C56=220 uF, C57=1 uF, C58=1 uF, and C116=10 uF. The inductor L3 of the optoelectronic device voltage control circuit 600 may have an inductance value of 620 milliHenry (mH). The resistors of the optoelectronic device voltage control circuit 600 may have the following resistance values: R52=10 kΩ, R53=~0 Ω, R54=4.99 kΩ, R55=17.8 kΩ, R56=5.6 kΩ, R57=0 Ω, R58=~0 Ω, R59=40.2 kΩ, R60=100 kΩ. In other examples, however, these capacitance, inductance and resistance values may be varied.

In some examples, the values of the resistors in the optoelectronic device voltage control circuit 600 are chosen to ensure the voltage range of VCTRL (e.g., 0 to 3.3 V) does not cause an overcurrent in the optoelectronic device (e.g., an LED, with resistor values for red, green, blue (R, G, B)). FIG. 6 shows a table 609 of example values of low voltage (VL), high voltage (VH), maximum VLED (VLEDmax), maximum current (Imax), Rt (e.g., R52), Rc (e.g., R55) and Rp (e.g., R56).

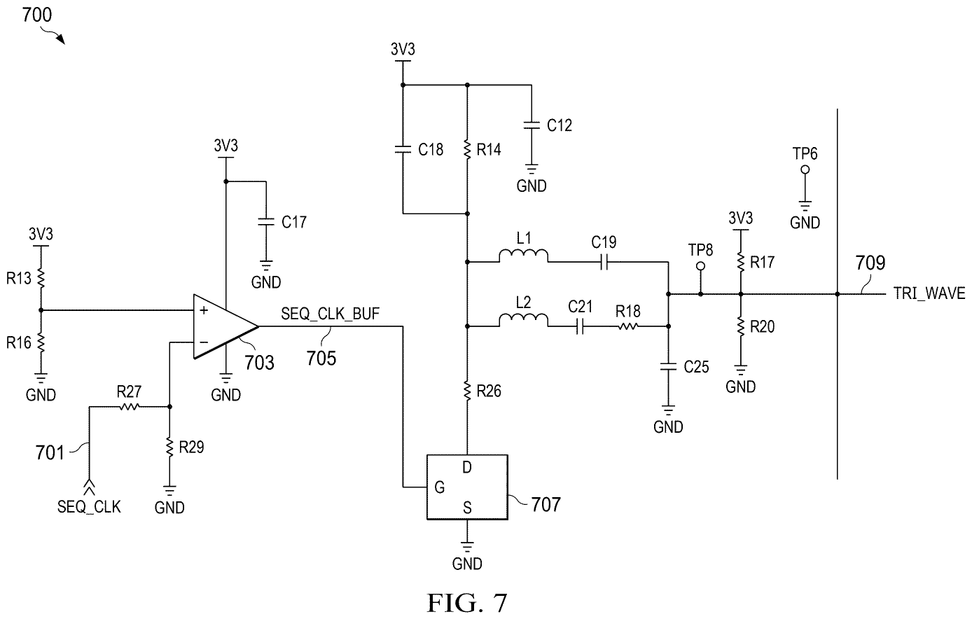

FIG. 7 shows a triangle wave generator circuit 700, which is an example of a circuit configured to generate a periodic waveform as described herein. The triangle wave generator circuit 700 generates as output a triangle wave signal 709 (TRI_WAVE) that is synchronized to an input clock signal 701 (SEQ_CLK). The input clock signal 701 is provided as one input to a comparator 703. The comparator 703 includes a first terminal (1) that provides as output a buffered clock signal 705 (SEQ_CLK_BUF). The buffered clock signal 705 is provided as input to a gate of transistor 707. The comparator 703 also includes a second terminal (2) coupled to ground (GND), a third terminal (3) coupled to a voltage source (3V3), a fourth terminal (4) coupled to the input clock signal 701, and a fifth terminal (5) coupled to a voltage source (3V3). The transistor 707 includes a first gate terminal (1) that receives as input the buffered clock signal 705, a second (source) terminal (2) coupled to ground (GND), and a third (drain) terminal (3) coupled via various inductors, capacitors and resistors to provide the output triangle wave signal 709.

The triangle wave generator circuit 700 generates a triangle-like waveform (the triangle wave signal 709, TRI_WAVE) synchronized to the input clock signal 701 (SEQ_CLK). The input clock signal 701 is passed to the comparator 703, which reforms the possibly distorted signal back into a square wave, provided as output as the buffered clock signal 705. In some examples, the resistors R27 and R29 are pads to add phase shift passives, if needed. The transistor 707, implemented as an n-type FET (NFET), pulls down the low side of resistor R14 when on, and R14 is pulled back up when the transistor 707 is off. The value of capacitor C18 controls the rate of drain and charge. The triangle wave signal 709 is filtered, and its direct current (DC) component is changed to a fixed value (e.g., 1.65 V).

The triangle wave generator circuit 700 includes various capacitors (C), inductors (L) and resistors (R) interconnected as illustrated. In some examples, the capacitors in the triangle wave generator circuit 700 have the following capacitance values: C12=1 uF, C17=1 uF, C18=2700 pF, C19=39 nF, C21=39 nF, C25=10 pF. The inductors in the triangle wave generator circuit 700 may have the following inductance values: L1=39 nH, and L2=39 nH. The resistors in the triangle wave generator circuit 700 may have the following resistance values: R13=10 kΩ, R14=10 Ω, R16=10 kΩ, R17=100 R14=10 Ω, R18=200 Ω, R20=R14=100 Ω, R26=4.7 Ω, R27=~0 Ω, R29=~0 Ω. In other examples, however, these capacitance, inductance and resistance values may be varied.

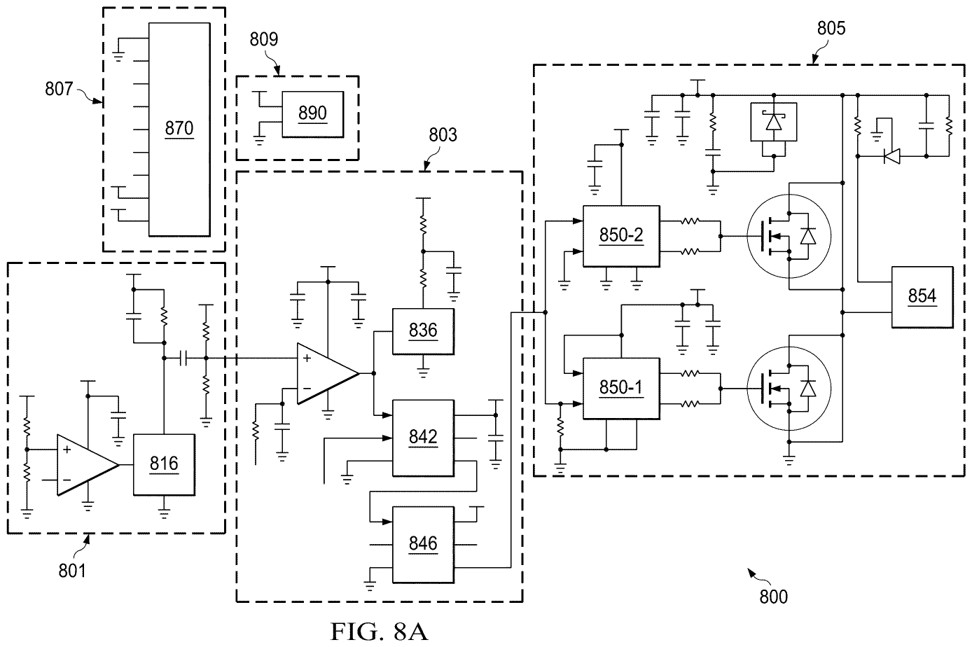

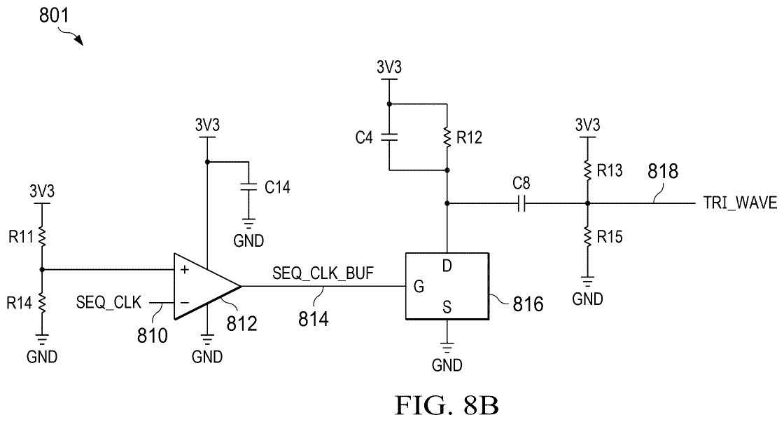

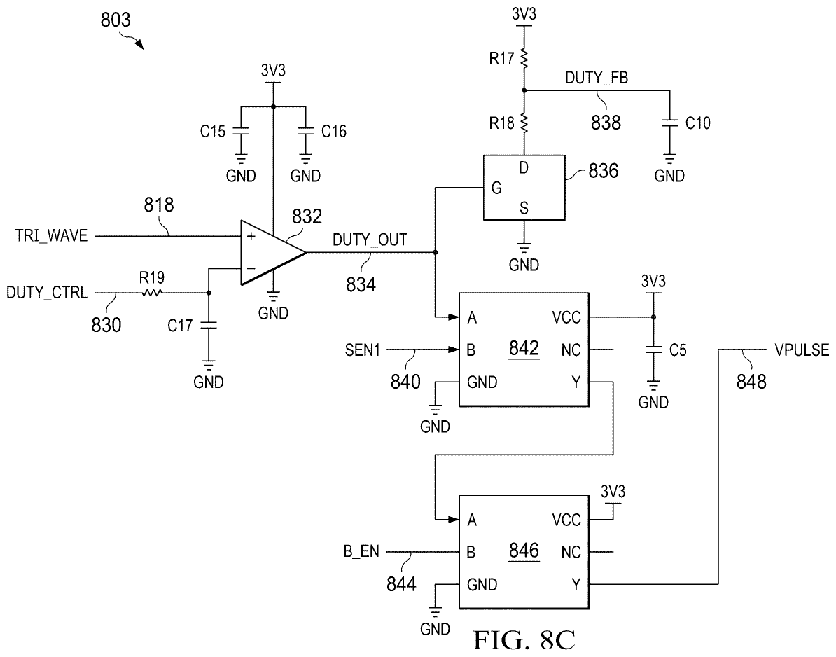

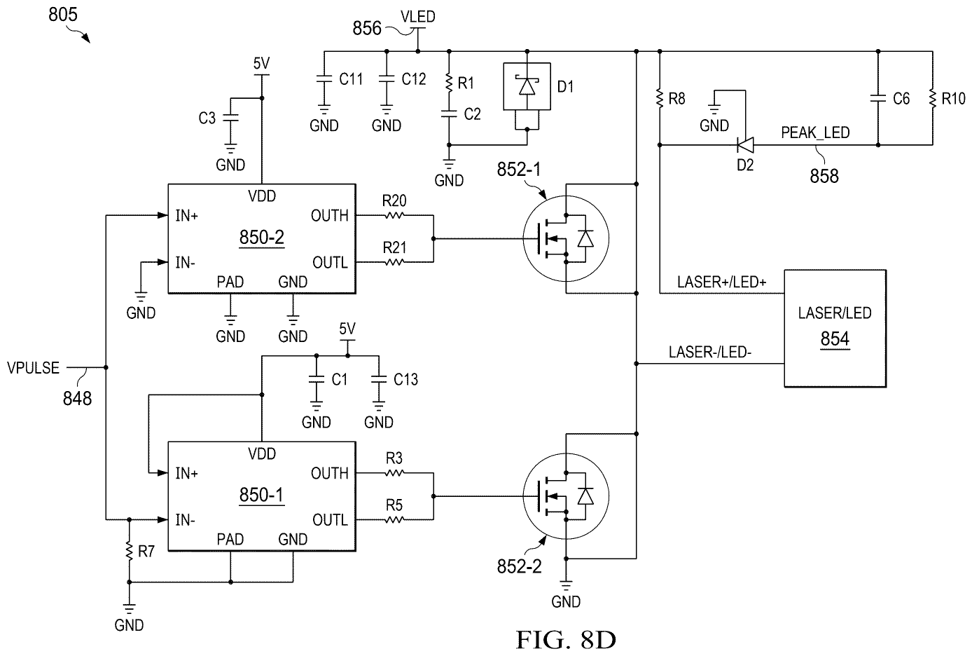

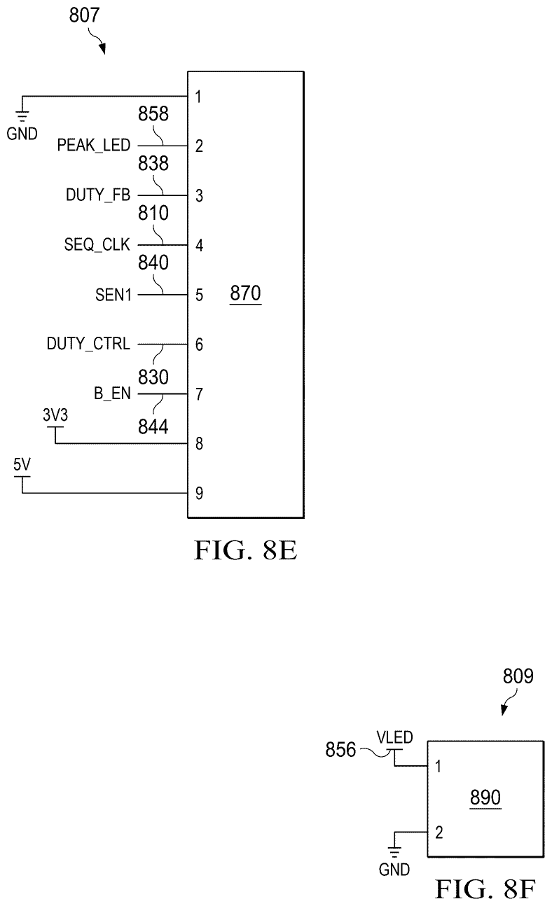

Referring now to FIGS. 8A-8F, a circuit diagram of a system 800 implementing an optoelectronic device controller is shown. FIG. 8A shows an overall view of the system 800, which includes a triangle wave generator circuit 801, a HSPWM generator circuit 803, and an optoelectronic device control circuit 805. FIG. 8A further shows inputs 807 and 809.

FIG. 8B show the triangle wave generator circuit 801, which provides functionality similar to that of the triangle wave generator circuit 700 described above. The triangle wave generator circuit 801 produces as output a triangle wave signal 818 (TRI_WAVE) that is synchronized to an input clock signal 810 (SEQ_CLK). The input clock signal 810 is provided as an input to a comparator 812, which outputs a buffered clock signal 814 (SEQ_CLK_BUF) provided as input to a gate of a transistor 816. The input clock signal 810 is passed to the comparator 812, which reforms the possibly distorted signal back into a square wave, provided as output as the buffered clock signal 814. The transistor 816, which in some examples is implemented as an NFET, pulls down the low side of resistor R12 when on, and R12 is pulled back up when the transistor 816 is off. The value of capacitor C8 controls the rate of drain and charge. The triangle wave signal 818 is filtered, and its DC component is changed to a fixed value (e.g., 1.65 V).

FIG. 8C shows the HSPWM generator circuit 803, which provides functionality similar to that of the HSPWM circuit 500 described above. The HSPWM generator circuit 803 receives the triangle wave signal 818 from the triangle wave generator circuit 801 as well as a duty cycle control generation signal 830 (DUTY_CTRL), which are provided as inputs to comparator 832. The comparator 832 outputs a duty cycle output signal 834 (DUTY_OUT). The duty cycle output signal 834 is provided to a gate of transistor 836, with a drain of the transistor 836 being coupled via resistor R18 to a signal 838 (DUTY_FB), providing optional feedback to the controller for duty cycle control. The duty cycle output signal 834 as well as signal 840 (SEN1) are provided to logic gate 842 (e.g., a NOR gate), with the output of the logic gate 842 (from terminal Y) being provided as input along with signal 844 (B_EN) to logic gate 846 (e.g., a NAND gate). The signals 840 (SEN1) and 844 (B_EN) are signals controlling an on/off state of the optoelectronic device 854. In some examples, both the signal 840 (SEN1) and the signal 844 (B_EN) must be in a specific state to turn on the optoelectronic device 854. The output of the logic gate 846 (from terminal Y) provides a voltage pulse signal 848 (VPULSE).

FIG. 8D shows the optoelectronic device control circuit 805 (also referred to as control circuit 805), which provides functionality similar to that of the control circuit 400 described above. The control circuit 805 receives the voltage pulse signal 848 from the HSPWM generator circuit 803, which is provided to a set of FET drivers 850-1 and 850-2 (collectively, FET drivers 850), having outputs coupled to control FETs 852-1 and 852-2 (collectively, FETs 852). The FETs 852 are coupled to optoelectronic device 854 (e.g., an LED, a laser). The optoelectronic device 854 is also coupled to a constant voltage source 856 (VLED). A peak voltage signal 858 (PEAK_LED) is tracked over time for peak current detection.

FIG. 8E shows inputs 807, including a connector 870 that connects hardware and signaling in the system 800, including: ground (GND), 3V3 and 5 V voltage supplies; the tracked peak voltage signal 858 (PEAK_LED), the signal 838 (DUTY_FB); the input clock signal 810 (SEQ_CLK); the signal 840 (SEN1); the duty cycle control generation signal 830 (DUTY_CTRL); and the signal 844 (B_EN).

FIG. 8G shows input 809 of the system 800, including a connector 890 that connects hardware and signaling including a constant voltage source 856 (VLED) and ground (GND).

The system 800 includes various capacitors (C), diodes (D) and resistors (R) which are interconnected with various other components of the triangle wave generator circuit 801, the HSPWM generator circuit 803, and the control circuit 805 as illustrated in FIGS. 8A-8D. In some examples, the capacitors in the system 800 have the following capacitance values: C1=1 uF, C2=1 nF, C3=1 uF, C4=2700 pF, C5=1 uF, C6=30 pF, C8=1 uF, C10=10 nF, C11=10 uF, C12=1 uF, C13=10 uF, C14=1 uF, C15=10 uF, C16=1 uF, C17=10 uF. The diode D1 (e.g., in the control circuit 805) may be a Schottky diode, and the diode D2 (e.g., in the control circuit 805) may be a junction diode. The resistors in the system 800 may have the following resistance values: R1=1 Ω, R3=200 mΩ, R5=200 mΩ, R7=10 kΩ, R8=100 mΩ, R10=47 kΩ, R11=10 kΩ, R12=10 Ω, R13=100 Ω, R14=10 kΩ, R15=100 Ω, R17=470 Ω, R18=10 Ω, R19=20 kΩ, R20=200 mΩ, R21=200 mΩ. In other examples, however, these capacitance and resistance values may be varied.

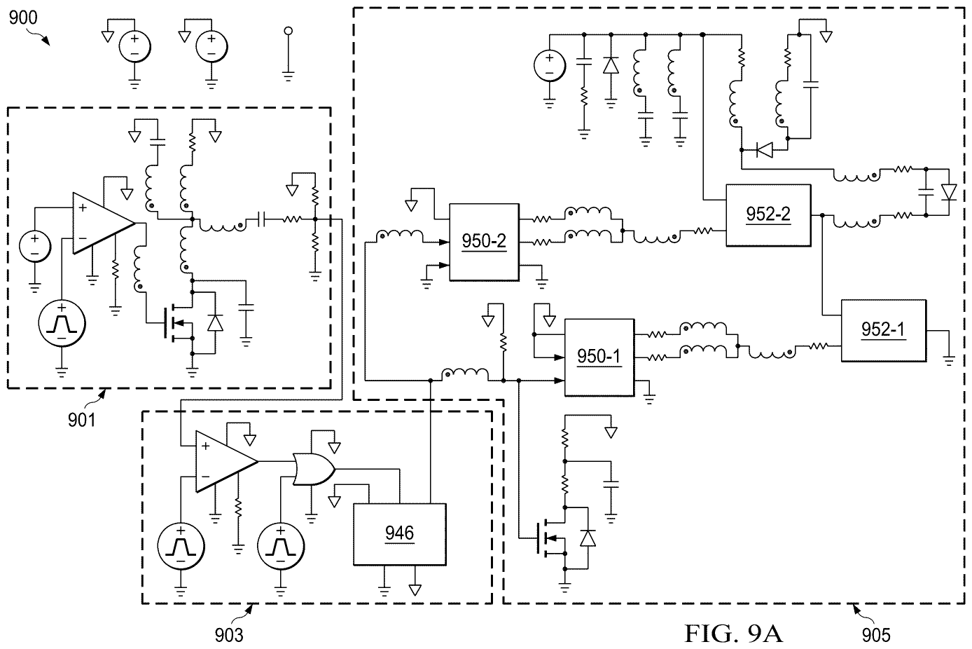

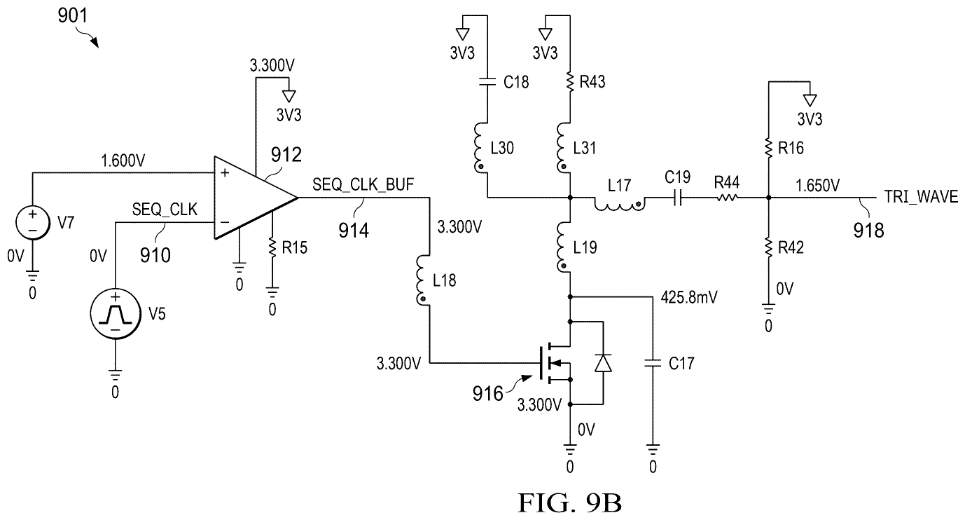

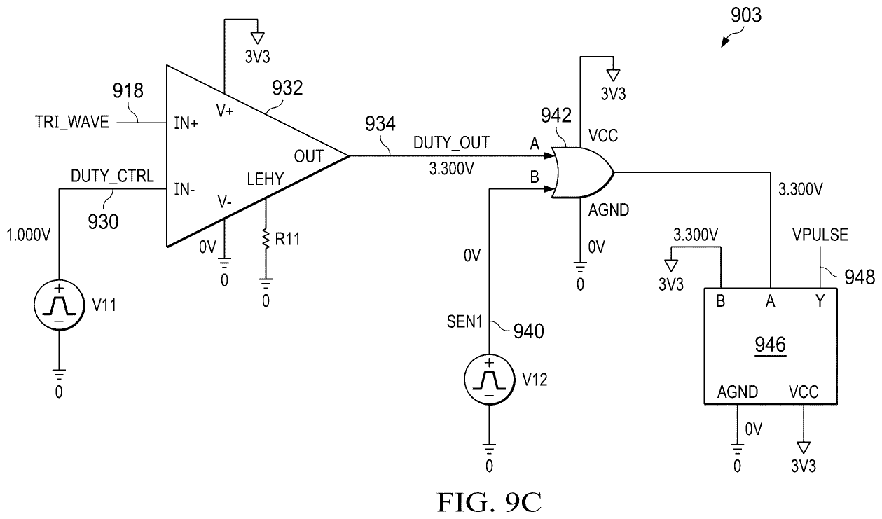

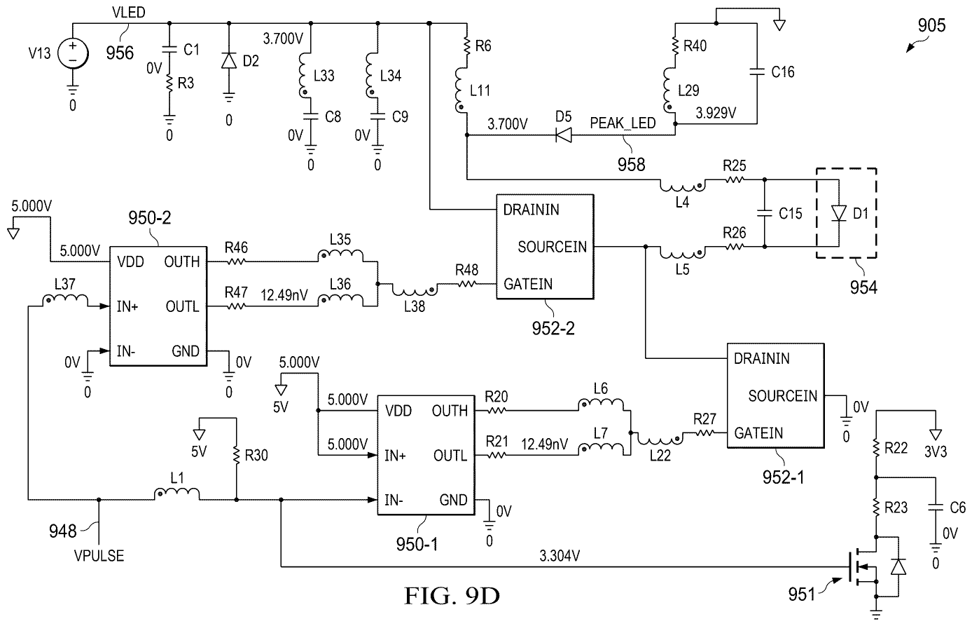

Referring now to FIGS. 9A-9D, a circuit diagram of a system 900 implementing an optoelectronic device controller is shown. FIG. 9A shows an overall view of the system 900, which includes a triangle wave generator circuit 901, a HSPWM generator circuit 903, and an optoelectronic device control circuit 905.

FIG. 9B show the triangle wave generator circuit 901, which provides functionality similar to that of the triangle wave generator circuit 700 described above. The triangle wave generator circuit 901 produces as output a triangle wave signal 918 (TRI_WAVE) that is synchronized to an input clock signal 910 (SEQ_CLK) produced by a voltage pulse generator (V5). The input clock signal 910 is provided as an input to a comparator 912 along with a DC signal produced by a voltage source (V7). FIG. 9B shows an example of a point in time of operation of the system 900 where the DC signal from the voltage source V7 is at 1.6 V, and the input clock signal 910 is at 0 V. The voltages at various other points in the triangle wave generator circuit 901 are labeled as shown in FIGS. 9A-9D accordingly, including a value of 1.65 V for the triangle wave signal 918. The comparator 912 outputs a buffered clock signal 914 (SEQ_CLK_BUF) provided as input to a gate of transistor 916. The input clock signal 910 is passed to the comparator 912, which reforms the possibly distorted signal back into a square wave, provided as output as the buffered clock signal 914. The transistor 916, which in some examples is implemented as an NFET, pulls down the low side of resistor R43 when on, and R43 is pulled back up when the transistor 916 is off. The value of capacitor C19 controls the rate of drain and charge. The triangle wave signal 918 is filtered, and its DC component is changed to a fixed value (e.g., 1.65 V).

FIG. 9C shows the HSPWM generator circuit 903, which provides functionality similar to that of the HSPWM circuit 500 described above. The HSPWM generator circuit 903 receives the triangle wave signal 918 from the triangle wave generator circuit 901 as well as a duty cycle control generation signal 930 (DUTY_CTRL) provided by a voltage pulse generator (V11). The triangle wave signal 918 and the duty cycle control generation signal 930 are provided as inputs to comparator 932. The comparator 932 provides as output a duty cycle output signal 934 (DUTY_OUT). The duty cycle output signal 934 and a signal 940 (SEN1) are provided as inputs to logic gate 942 (e.g., an OR gate), with the output of the logic gate 942 (terminal Y) being provided as input to a first terminal (A) of logic gate 946 (e.g., an AND gate). The logic gate 946 also receives at a second terminal (B) a 3V3 voltage. The output of the logic gate 946 (terminal Y) provides a voltage pulse signal 948 (VPULSE).

FIG. 9D shows the optoelectronic device control circuit 905 (also referred to as control circuit 905), which provides functionality similar to that of the control circuit 400 described above. The control circuit 905 receives the voltage pulse signal 948 from the HSPWM generator circuit 903, which is provided to a set of FET drivers 950-1 and 950-2 (collectively, FET drivers 950), having outputs coupled to control FETs 952-1 and 952-2 (collectively, FETs 952). As shown, the FET driver 950-1 is also coupled to transistor 951 for optional monitoring of the average duty cycle by the controller. The FETs 952 are coupled to optoelectronic device 954 (e.g., an LED, a laser). The optoelectronic device 954 is also coupled to a constant voltage source 956 (VLED) provided by a voltage source V13. A peak voltage signal 958 (PEAK_LED) is tracked over time for peak current detection.

The system 900 includes various capacitors (C), diodes (D), inductors (L) and resistors (R) which are interconnected with various other components of the triangle wave generator circuit 901, the HSPWM generator circuit 903, and the control circuit 905 as illustrated in FIGS. 9A-9D. In some examples, the capacitors in the system 900 have the following capacitance values: C1=1 nF, C6=10 nF, C8=10 uF, C9=1 uF, C15=3 nF, C16=30 pF, C17=3 pF, C18=5000 pF, and C19=1 uF. The diodes D2 and D5 in the system 900 may be junction diodes. The inductors in the system 900, which may be used for simulation purposes, may have the following inductance values: L1=0.5 nH, L4=300 pH, L5=300 pH, L6=500 pH, L7=500 pH, L11=200 pH, L17=1 nH, L18=1 nH, L19=200 pH, L22=1 nH, L29=1 nH, L30=500 pH, L31=500 pH, L33=500 pH, L34=500 pH, L35=500 pH, L36=500 pH, and L38=0.5 nH. The resistors in the system 900 may have the following resistance values: R3=1 Ω, R6=100 mΩ, R11=400 kΩ, R15=200 kΩ, R16=100 Ω, R23=10 Ω, R20=200 mΩ, R21=200 mΩ, R22=470 Ω, R25=1 mΩ, R26=1 mΩ, R27=1 Ω, R30=10 kΩ, R40=50 kΩ, R42=100 Ω, R43=10 Ω, R44=1 Ω, R46=200 mΩ, R47=200 mΩ, and R48=1 Ω. In other examples, however, these capacitance, inductance and resistance values may be varied. Further, the particular voltage values labeled in FIGS. 9A-9D may vary during operation of the system 900.

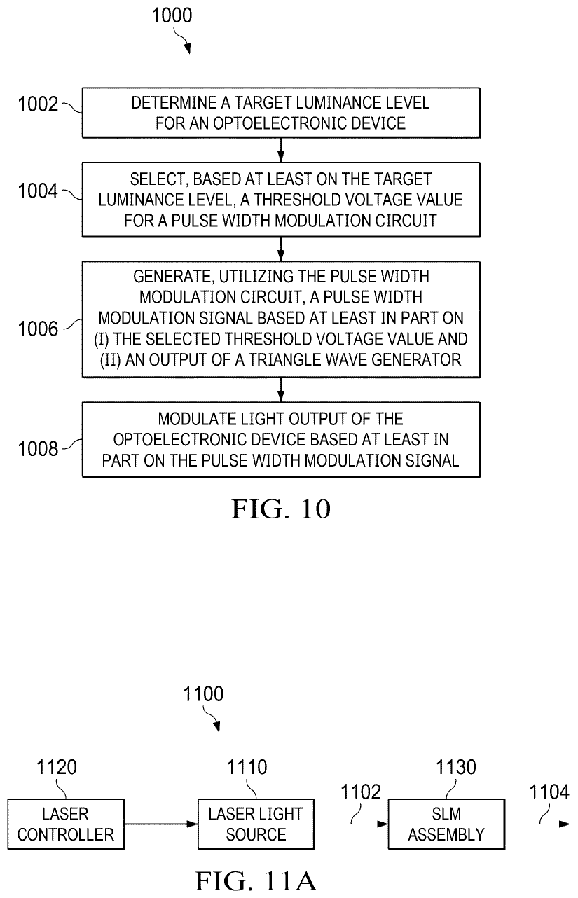

Referring now to FIG. 10, a process flow 1000 for utilizing an optoelectronic device controller (e.g., controller 102 in system 100, controller 202 in system 200) for modulating light output of an optoelectronic device (e.g., LED 116 in system 100, LED/laser 216 in system 200) is shown. The process flow 1000 begins with step 1002, determining a target luminance level for the optoelectronic device. In step 1004, a threshold voltage value for a PWM circuit (e.g., pulse generator circuit 206 in system 200) is selected based at least on the target luminance level. In step 1006, a PWM signal is generated utilizing the PWM circuit. The PWM signal is based at least in part on (i) the selected threshold voltage value and (ii) a periodic waveform (e.g., an output of the triangle wave generator 106 in system 100). A duration of one or more pulses of the PWM signal is based at least in part on the selected threshold voltage value. In step 1008, light output of the optoelectronic device is modulated based at least in part on the PWM signal.

Modulating the light output of the optoelectronic device may include generating a voltage pulse signal controlling switching of the optoelectronic device on and off as a logical AND of an optoelectronic device enable control signal and the PWM signal. The process flow 1000 may also include monitoring, utilizing a peak detector circuit (e.g., peak detector circuit 122 in system 100, peak detector feedback signal 217 in system 200), a peak current of the optoelectronic device, the peak detector circuit being configurable to track a peak voltage across a current sense resistor (e.g., current sense resistor 118 in system 100) in a current path of the optoelectronic device, and controlling an output voltage level of a constant voltage source (e.g., voltage source 120 in system 100, voltage-controlled Buck converter 218 in system 200) for the optoelectronic device based at least in part on the monitored peak current of the optoelectronic device.

Light projection systems can be used in a wide variety of different display applications. Light projection systems may utilize optoelectronic devices such as LEDs (e.g., LED diodes) and/or lasers (e.g., laser diodes). Light projection systems may be used for viewing images or video in some examples. In other examples, light projection systems may be used for projecting images from an automobile onto a surface outside of the automobile. In other examples, light projection systems may be an augmented reality HUD in an automobile. The HUD may display various information to the driver or other passengers in the automobile. Light projection systems may be used for automotive headlights in other examples.

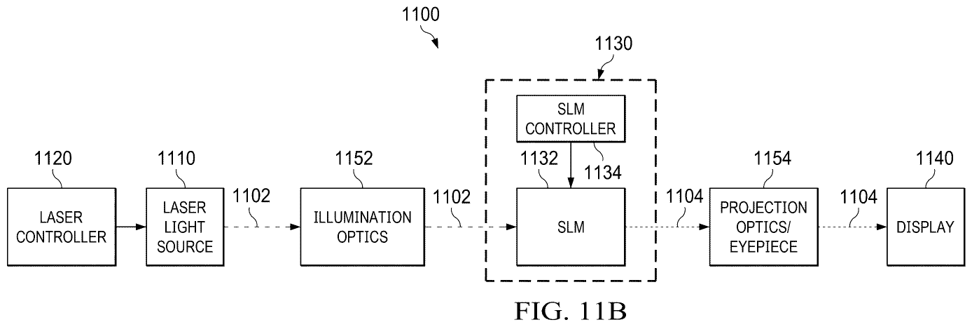

Referring now to FIG. 11A, a block diagram of a light projection system 1100 is shown. In the illustrated example of FIG. 11A, the light projection system 1100 includes a laser light source 1110 (e.g., an example of one or more optoelectronic devices providing light sources), a laser controller 1120 (e.g., an example of an optoelectronic device controller), and a spatial light modulator (SLM) assembly 1130. The laser controller 1120 can be configured to control the laser light source 1110 to emit an illumination beam 1102. The laser light source 1110 and the spatial light modulator assembly 1130 are optically coupled and arranged such that the illumination beam 1102 illuminates an SLM of the SLM assembly 1130, which modulates the illumination beam 1102 to produce a projection beam 1104. According to some examples, the laser controller 1120 implements a control scheme to control the laser light source 1110 to emit the illumination beam 1102 having controlled brightness as described herein.

Referring now to FIG. 11B, a block diagram of an example of the light projection system 1100 of FIG. 11A is shown. In the FIG. 11B example, the light projection system 1100 includes a display 1140 to which the projection beam 1104 is directed. The display 1140 may include a device with a display screen (e.g., a television, computing device, smartphone, etc.) or a display surface (e.g., a canvas or other projection screen, a wall, a window, a windshield, glasses, a roadway, or some other surface onto which images can be projected for viewing). As also shown, the SLM assembly 1130 includes an SLM 1132 and an SLM controller 1134. The SLM 1132 can be a micro-electromechanical device (e.g., a digital micromirror device (DMD)), a liquid crystal-based display device, or another projection device. The SLM controller 1134 can be configured to write image data representing an image to the SLM 1132 and to control the SLM 1132 to display, or project, the image when the SLM 1132 is illuminated by the illumination beam 1102 from the laser light source 1110.

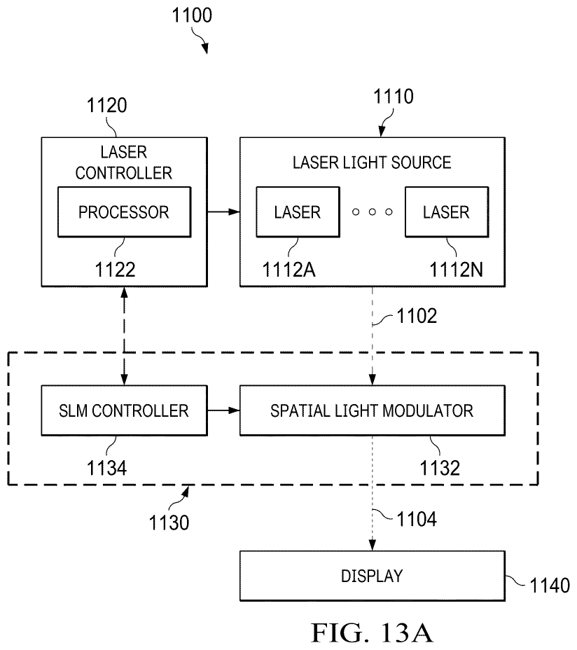

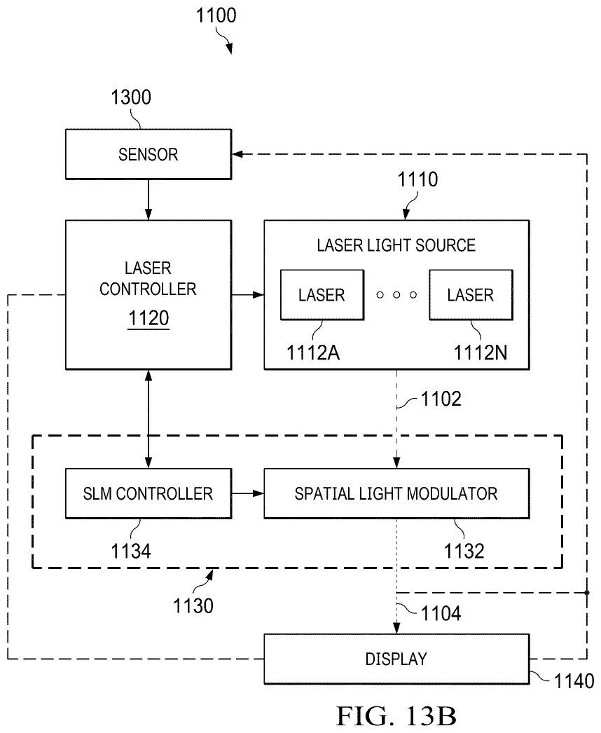

The image projected by the SLM 1132, represented by the projection beam 1104, for example, may be displayed on or by the display 1140. In some examples, to produce a desired projection beam 1104, the laser light source 1110 and the SLM 1132 may be operated together in a synchronized manner. For example, in some instances, the SLM controller 1134 can be configured to write the image data to the SLM 1132 using PWM timing signals as described herein. In some such examples, the SLM controller 1134 may be further configured to synchronize the PWM timing signals for the SLM 1132 with enable timing signals of the laser controller 1120 for the laser light source 1110 such that the laser light source 1110 can be controlled to appropriately illuminate the SLM 1132. Accordingly, in some examples, the SLM controller 1134 and the laser controller 1120 may be communicatively coupled, as illustrated in FIGS. 13A and 13B, for example, to achieve appropriate synchronization between the laser light source 1110 and the SLM 1132. In other examples, the laser controller 1120 and the SML controller 1134 may be implemented as a single controller that performs both functions (e.g., control of the laser light source 1110 and control of the SLM 1132).

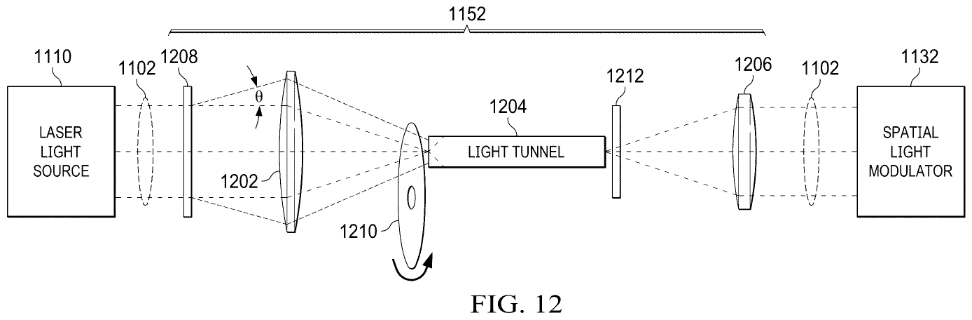

Continuing with the example of FIG. 11B, the light projection system 1100 may include illumination optics 1152 positioned in an optical path between the laser light source 1110 and the SLM 1132. Thus, the SLM 1132 and the laser light source 1110 may be optically coupled via the illumination optics 1152, such that the illumination optics 1152 direct the illumination beam 1102 to the SLM 1132. The illumination optics 1152 may include one or more lenses, mirrors, and/or other optical elements that condition (e.g., focus, collimate, diffuse, homogenize, perform chromatic and/or spatial aberration corrections, etc.) the illumination beam 1102 emitted by the laser light source 1110 and direct the illumination beam 1102 onto the SLM 1132. Examples of some optical elements that may be part of the illumination optics 1152 are described below with reference to FIG. 12. In addition, the light projection system 1100 may include projection optics 1154 (which in some examples includes an eyepiece, depending on the application of the light projection system 1100) that condition the projection beam output from the SLM 1132 and direct the projection beam 1104 to the display 1140. For example, the projection optics 1154 may include one or more mirrors and/or lenses. Thus, the display 1140 may be optically coupled to the SLM 1132 via the projection optics 1154.

Referring now to FIG. 12, a block diagram illustrating various components that may form part of the illumination optics 1152 is shown. The illumination optics 1152 may include a first optical element 1202 that images the illumination beam 1102 output from the laser light source 1110 onto a light tunnel 1204. The illumination optics 1152 may further include a second optical element 1206 that collimates light output from the light tunnel 1204 and directs the illumination beam 1102 onto the SLM 1132. In the FIG. 12 example, the first and second optical elements 1202, 1206 are represented by lenses. However, either or both of the first and second optical elements 1202, 1206 individually may comprise one or more lenses and/or one or more mirrors. The light tunnel 1204 conveys the illumination beam 1102 along at least a portion of the optical path between the laser light source 1110 and the SLM 1132. In some examples, the light tunnel 1204 includes a waveguide or integrator rod configured to homogenize the illumination beam 1102. In other examples, the light tunnel 1204 may be replaced with a different homogenizing optical element, such as a “fly's eye” array. The illumination optics 1152 may further comprise one or more optical elements for illumination despeckling to reduce laser speckle effects in the displayed projection beam 1104.

In some examples, the illumination optics 1152 may include an entrance static diffuser 1208 that is configured to expand the spot size of the illumination beam 1102 at the entrance to the light tunnel 1204. This may provide spatial diversity in the illumination beam 1102, which may reduce laser speckle. As illustrated, the entrance static diffuser 1208 may be positioned between the laser light source 1110 and the first optical element 1202. In other examples, the entrance static diffuser 1208 may be positioned between the first optical element 1202 and the entrance to the light tunnel 1204. Alternatively, in examples in which the first optical element 1202 comprises multiple lenses and/or mirrors, the entrance static diffuser 1208 may be positioned between individual components of the first optical element 1202.

In some examples, the illumination optics 1152 includes a moving diffuser 1210 that is configured to expand light within the pupil of the illumination optics 1152. This may provide angular diversity in the illumination beam 1102, which may also reduce laser speckle. The moving diffuser 1210 may be a rotating, laterally shifting, or tilting diffuser, for example. Although illustrated as a transmissive diffuser in FIG. 12, in other examples the moving diffuser 1210 can be a reflective diffuser, with appropriate modifications to the optical arrangement of components of the illumination optics 1152. In some examples, the illumination optics 1152 includes both the entrance static diffuser 1208 and the moving diffuser 1210, as illustrated in FIG. 12. In other examples, the illumination optics 1152 may include the moving diffuser 1210 and omit the entrance static diffuser 1208. In some examples, the moving diffuser 1210 is positioned proximate an entrance to the light tunnel 1204, as illustrated in FIG. 12. In other examples, the moving diffuser 1210 may be positioned anywhere between the laser light source 1110 and the entrance to the light tunnel 1204.

In some examples, the illumination optics 1152 includes an exit static diffuser 1212 positioned between an exit of the light tunnel 1204 and the SLM 1132. In some examples, the exit static diffuser 1212 is positioned proximate the exit of the light tunnel 1204, as shown in FIG. 12. In other examples, the exit static diffuser 1212 may be positioned elsewhere in the optical path between the exit of the light tunnel 1204 and the SLM 1132. The exit static diffuser 1212 positioned after the light tunnel 1204 may help to further homogenize the illumination beam 1102 within the pupil of the illumination optics 1152. In some examples, the illumination optics 1152 includes the exit static diffuser 1212 in combination with the entrance static diffuser 1208 and/or the moving diffuser 1210. In other examples, the illumination optics 1152 may include the exit static diffuser 1212 and omit the entrance static diffuser 1208 and/or the moving diffuser 1210.

Referring now to FIG. 13A, in some examples the laser light source 1110 includes a plurality of lasers 1112 (individually identified as lasers 1112A-1112N). Individual lasers 1112 may emit light in particular wavelength ranges and of different colors. For example, the laser light source 1110 may include at least three lasers 1112 configured to emit blue, red, and green light, respectively. In some examples, the laser light source 1110 may include multiple lasers 1112 configured to emit light of a particular color. For example, the laser light source 1110 may include one laser 1112 for each color (e.g., red, green, and blue), or more than one laser 1112 for some or all colors. Using multiple lasers 1112 for a particular color can reduce laser speckle by providing wavelength diversity in the illumination beam 1102. For example, the laser light source 1110 may include multiple lasers 1112 that emit light of similar wavelengths within the wavelength range that corresponds to a single color. For example, lasers 1112 configured to emit light with wavelengths of 640 nanometers (nm) and 645 nm both emit in the red region of the visible spectrum (and may be referred to as red lasers). The use of such, or similar, lasers in combination provides wavelength diversity in the red channel, which reduces the coherence of the light and thus may improve laser speckle. A similar approach may be used for blue, green, and/or other colors.

It will be appreciated that in some examples, the light projection system 1100 may include the use of multiple lasers for any one or more colors in addition to any one or more of the components described above with reference to FIG. 12. In other examples, the use of multiple lasers for any one or more colors may reduce or obviate the need for one or more of the entrance static diffuser 1208, the moving diffuser 1210, the exit static diffuser 1212, and/or other optical components configured to reduce laser speckle. Furthermore, examples of the laser control scheme described herein may be implemented in systems that use a single laser 1112 for emitting light of a particular color, and/or multiple lasers for emitting light of any one or more particular colors.

In some examples, the lasers 1112 of the laser light source 1110 are operated in a time sequential manner to produce pulses of light of different colors that together form the illumination beam 1102. Over the duration of a sequence period, one or more pulses of light of different colors may be emitted by the lasers 1112, with these individual color pulses being integrated over the sequence period to form the illumination beam 1102. In some examples, the duration of the sequence period is less than the critical flicker fusion rate, such that an observer of the illumination beam 1102 sees a continuous white/gray beam, rather than the individual pulses of different colors. The duration and intensity of the pulses of different colors, in any given sequence period, determine an overall color gamut and white point of the illumination beam 1102. In some examples, the duration of the sequence period is equal to a frame period, namely the duration for which the SLM 1132 is controlled to project, as the projection beam 1104, a single frame of image data to be displayed on the display 1140.

The laser controller 1120, implementing processor 1122, can be configured to control the duration and/or intensity of the light emitted by the individual lasers 1112 to desaturate the color gamut of the illumination beam 1102 and to select a desired white point of the illumination beam 1102. In some laser systems, the individual lasers are controlled such that when a laser (or laser group) of one color is emitting (e.g., red), the lasers (or laser groups) of other colors (e.g., blue and green) are turned off. In contrast, the laser controller 1120 according to examples described herein can be configured to drive the laser light source 1110 such that, while the laser(s) of one color are controlled to emit light of that color with relatively high optical power, some or all of the lasers of other colors are controlled to emit light of the other color(s) with varying levels of relatively low optical power. Thus, during any one color sequence or channel, lasers configured to emit other colors can be controlled to add small amounts of those colors to the channel. This simultaneous operation of lasers 1112 of multiple colors provides a blending that may reduce color saturation, while also adding wavelength diversity to reduce laser speckle and increasing the brightness of the illumination beam 1102.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. An optoelectronic device controller comprising:
a first circuit configurable to generate a pulse width modulation signal based at least in part on (i) an adjustable threshold voltage and (ii) a periodic waveform; and
a second circuit configurable to modulate light output of an optoelectronic device based at least in part on the pulse width modulation signal.

2. The optoelectronic device controller of claim 1, wherein the periodic waveform is an output of a triangle wave generator.

3. The optoelectronic device controller of claim 1, wherein the optoelectronic device is one of a laser and a light-emitting diode.

4. The optoelectronic device controller of claim 1, wherein the adjustable threshold voltage controls a duration of pulses of the pulse width modulation signal.

5. The optoelectronic device controller of claim 1, further comprising a third circuit providing a clock source shared by the first circuit and the second circuit.

6. The optoelectronic device controller of claim 5, wherein the second circuit is configurable:
to generate an optoelectronic device enable control signal synchronized to the clock source; and
to generate a voltage pulse signal controlling switching of the optoelectronic device on and off as a logical AND of the optoelectronic device enable control signal and the pulse width modulation signal.

7. The optoelectronic device controller of claim 6, wherein the second circuit is configurable:
to apply the voltage pulse signal to a transistor, the transistor gating current through the optoelectronic device based at least in part on the voltage pulse signal.

8. The optoelectronic device controller of claim 7, wherein the voltage pulse signal is applied to the transistor via a field-effect transistor driver.

9. The optoelectronic device controller of claim 1, further comprising a third circuit configurable:
to monitor a peak current of the optoelectronic device utilizing a peak detector circuit, the peak detector circuit tracking a peak voltage across a current sense resistor in a current path of the optoelectronic device; and
to control an output voltage level of a constant voltage source for the optoelectronic device based at least in part on the peak current.

10. The optoelectronic device controller of claim 9, wherein the third circuit is further configurable to control the output voltage level of the constant voltage source at least in part on at least one of:
a temperature of the optoelectronic device;
a duty cycle of the optoelectronic device;
an amount of time that the optoelectronic device has been on;
aging of hardware component of the optoelectronic device; and
a measured efficiency of the optoelectronic device.

11. The optoelectronic device controller of claim 1, wherein the second circuit is configurable to modulate the light output of the optoelectronic device to provide luminance control for the optoelectronic device.

12. A light projection system comprising:
a laser light source configured to emit a laser beam; and
a laser controller comprising:
a first circuit configurable to generate a pulse width modulation signal based at least in part on (i) an adjustable threshold voltage and (ii) a periodic waveform; and
a second circuit configurable to modulate the laser beam emitted by the laser light source based at least in part on the pulse width modulation signal.

13. The light projection system of claim 12, wherein the first circuit of the laser controller is configurable to set the adjustable threshold voltage to control a duration of one or more pulses of the pulse width modulation signal, a luminance of the laser beam being based at least in part on the duration of the one or more pulses of the pulse width modulation signal.

14. The light projection system of claim 12, wherein the second circuit of the laser controller is configurable:
to generate a laser enable control signal synchronized to a clock source; and
to generate a voltage pulse signal controlling switching of the laser light source on and off as a logical AND of the laser enable control signal and the pulse width modulation signal.

15. The light projection system of claim 12, wherein the laser controller further comprises a third circuit configurable:
to monitor a peak current of the laser light source utilizing a peak detector circuit, the peak detector circuit tracking a peak voltage across a current sense resistor in a current path of the laser light source; and
to control an output voltage level of a constant voltage source for the laser light source based at least in part on the peak current.

16. A method comprising:
determining a target luminance level for an optoelectronic device;
selecting, based at least on the target luminance level, a threshold voltage value for a pulse width modulation circuit;
generating, utilizing the pulse width modulation circuit, a pulse width modulation signal based at least in part on (i) the selected threshold voltage value and (ii) a periodic waveform; and
modulating light output of the optoelectronic device based at least in part on the pulse width modulation signal.

17. The method of claim 16, wherein the optoelectronic device comprises one of a laser and a light-emitting diode.

18. The method of claim 16, wherein a duration of one or more pulses of the pulse width modulation signal is based at least in part on the selected threshold voltage value.

19. The method of claim 16, wherein modulating the light output of the optoelectronic device comprises generating a voltage pulse signal controlling switching of the optoelectronic device on and off as a logical AND of an optoelectronic device enable control signal and the pulse width modulation signal.

20. The method of claim 16, further comprising:
monitoring, utilizing a peak detector circuit, a peak current of the optoelectronic device, the peak detector circuit being configurable to track a peak voltage across a current sense resistor in a current path of the optoelectronic device; and
controlling an output voltage level of a constant voltage source for the optoelectronic device based at least in part on the monitored peak current of the optoelectronic device.
